(19) United States
(12) Patent Application Publication
(10) Pub. No.: US 2017/0250240 A1
(43) Pub. Date: Aug. 31, 2017

(54) DISPLAY DEVICE

(71) Applicant: Japan Display Inc., Tokyo (JP)

(72) Inventors: Haochun LEE, Tokyo (JP); Masaru UCHIYAMA, Tokyo (JP); Masaya ADACHI, Tokyo (JP)

(21) Appl. No.: 15/373,766

(22) Filed: Dec. 9, 2016

(30) Foreign Application Priority Data
Feb. 26, 2016 (JP) 2016-035069

(51) Int. Cl. H01L 27/32; H01L 27/12; G09G 3/3266

(52) U.S. Cl. CPC H01L 27/3276; G09G 3/3266; H01L 27/124; H01L 27/3218; H01L 27/3272

(57) ABSTRACT

Provided is a display device including: a first gate line and a second gate line which extend in a first direction; a signal line and a current-supplying line which extend in a second direction intersecting with the first direction; a first sub-pixel surrounded by the first gate line, the second gate line, the signal line, and the current-supplying line; and a light-shielding film located over the first sub-pixel. The light-shielding film has a first opening portion and a second opening portion, and the first sub-pixel overlaps with the first opening portion and the second opening portion and has an emission region and a light-transmitting region. In the light-transmitting region, a distance in the first direction between the signal line and the current-supplying line continuously changes along the second direction.

### CROSS REFERENCE TO RELATED APPLICATIONS

This application is based on and claims the benefit of priority from the prior Japanese Patent Application No. 2016-035069, filed on Feb. 26, 2016, the entire contents of which are incorporated herein by reference.

### FIELD

The present invention relates to a display device. For example, the present invention relates to a display device having a light-transmitting property.

### BACKGROUND

A display device having a plurality of pixels formed over a substrate has been known. As a typical example of such a display device, a liquid crystal display device and an EL display device are represented.

An EL display device is a display device having, in each pixel, a light-emitting element with a structure in which a material exhibiting an electroluminescence (EL) phenomenon is sandwiched between a pair of electrode. A light-emitting element using an organic compound as a material is called an organic light-emitting element, an organic EL element, or an organic electroluminescence element. A display device having a plurality of such organic light-emitting elements is called an organic EL display device.

Apart from a liquid crystal display device, an organic EL display device does not require a backlight. Therefore, the use of a light-transmitting electrode for both of a pair of electrodes allows a user to detect light (hereinafter, referred to as transmitting light) from a side opposite to the user with respect to a display device. Even though one of the pair of electrodes does not have a light-transmitting property, the transmitting light can be detected by forming a light-transmitting region which does not include any light-emitting element, in addition to an emission region. Such a display device is called a transparent display device and is disclosed in Japanese patent application publication 2011-186427, for example.

### SUMMARY

An embodiment of the present invention is a display device including: a first substrate; a first gate line and a second gate line located over the first substrate and extend in a first direction; a signal line and a current-supplying line located over the first substrate and extend in a second direction intersecting with the first direction; a first sub-pixel surrounded by the first gate line, the second gate line, the signal line, and the current-supplying line; and a light-shielding film located over the first sub-pixel. The light-shielding film has a first opening portion and a second opening portion, and the first sub-pixel overlaps with the first opening portion and the second opening portion and has an emission region and a light-transmitting region. In the light-transmitting region, a distance in the first direction between the signal line and the current-supplying line continuously changes along the second direction. Alternatively, a portion of the signal line and a portion of the current-supplying line, which are adjacent to the light-transmitting region, have a bending point.

An embodiment of the present invention is a display device including: a first emission region; a second emission region adjacent to the first emission region in a first direction; a first light-transmitting region adjacent to the first emission region in a second direction intersecting with the first direction; and a second light-transmitting region adjacent to the first light-transmitting region in the first direction and adjacent to the second emission region in the second direction, where a distance of the first light-transmitting region in the first direction includes a first distance and a second distance smaller than the first distance.

### BRIEF DESCRIPTION OF DRAWINGS

FIG. 1 is a top view of a display device of an embodiment of the present invention;

FIG. 2A and FIG. 2B are respectively a top view of a display device of an embodiment of the present invention and a drawing schematically showing a variation of a width of a light-transmitting region;

FIG. 3 is a top view of a sub-pixel of a display device of an embodiment of the present invention;

FIG. 4 is a top view of a light-shielding film over a sub-pixel of a display device of an embodiment of the present invention;

FIG. 5 is a cross-sectional view of a display device of an embodiment of the present invention;

FIG. 6 is a cross-sectional view of a display device of an embodiment of the present invention;

FIG. 7 is a cross-sectional view of a display device of an embodiment of the present invention;

FIG. 8 is a cross-sectional view of a display device of an embodiment of the present invention;

FIG. 9 is a top view of a display device of an embodiment of the present invention;

FIG. 10 is a top view of a display device of an embodiment of the present invention;

FIG. 11 is a top view of a display device of an embodiment of the present invention;

FIG. 12 is a top view of a display device of an embodiment of the present invention;

FIG. 13 is a top view of a display device of an embodiment of the present invention;

FIG. 14 is a top view of a display device of an embodiment of the present invention;

FIG. 15 is a top view of a display device of an embodiment of the present invention;

FIG. 16 is a top view of a conventional transparent display device; and

FIG. 17 is a diffraction pattern of light after passing through a conventional transparent display device.

### DESCRIPTION OF EMBODIMENTS

Hereinafter, each embodiment of the present invention is explained with reference to the drawings. However, the invention can be implemented in a variety of different modes within its concept and should not be interpreted as being limited to the disclosure of the following embodiments.

In the drawings, the width, thickness, shape, and the like of each component may be schematically illustrated and different from those of an actual mode in order to provide a clearer explanation. However, the drawings simply give an example and do not limit the interpretation of the present invention. In the specification and each of the drawings, the same reference number is provided to an element which is the same as that appearing in preceding drawings, and a detailed explanation may be omitted as appropriate.

### First Embodiment

### 1. Layout of Sub-Pixel

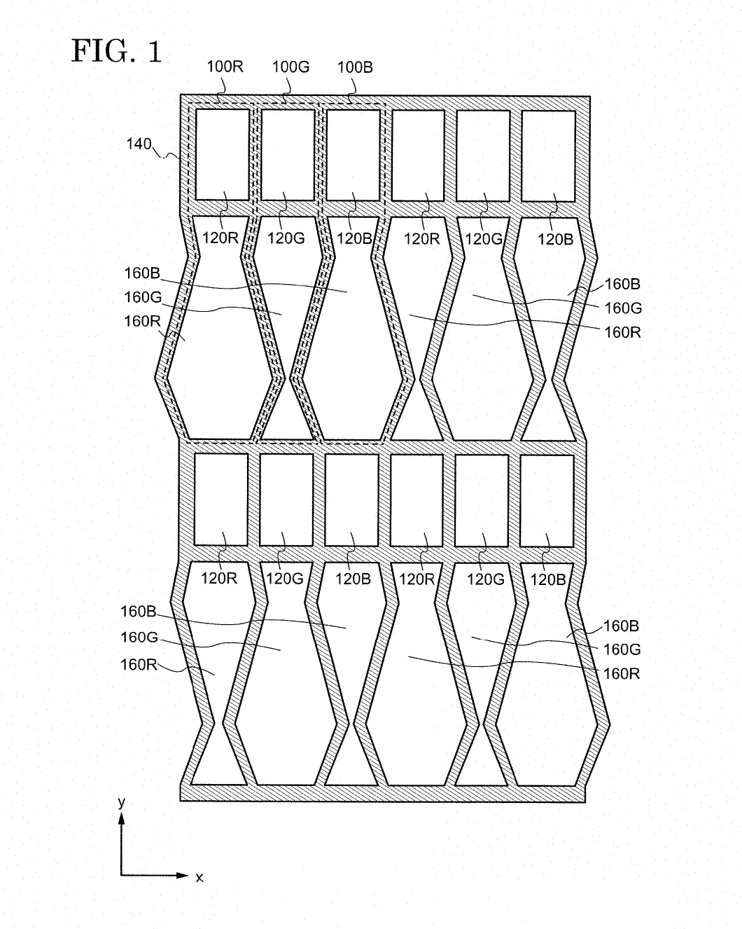

A schematic top view of a display device of an embodiment of the present invention is shown in FIG. 1. As shown in FIG. 1, the display device has a plurality of sub-pixels 100 surrounded by a dotted line. In the present invention, a structure is shown in which sub-pixels 100R, 100G, and 100B respectively giving red, green, and blue emissions are arranged in a matrix form (matrix of 2 lines and 6 columns in FIG. 1).

Each sub-pixel 100 has an emission region 120 and a light-transmitting region 160. Therefore, the display device of the present embodiment functions as a so-called transparent display device. As described below, a light-emitting element is disposed in the emission region 120, while the light-transmitting region 160 is configured to transmit ambient light. Here, an emission region 120R and a light-transmitting region 160R are provided in the sub-pixel 100R giving red emission. Similarly, an emission region 120G and a light-transmitting region 160G are disposed in the sub-pixel 100G giving green emission, and an emission region 120B and a light-transmitting region 160B are disposed in the sub-pixel 1008 giving blue emission. Note that the embodiment of the present invention is not limited to such a sub-pixel arrangement, and a sub-pixel giving white or yellow emission and the like may be formed in addition to the aforementioned sub-pixels.

The display device may further possess a light-shielding film 140 over a region surrounding each sub-pixel 100 and a region which divides the emission region 120 from the light-transmitting region 160. In other words, each sub-pixel 100 has the light-shielding film 140 thereover, and the light-shielding film 140 may have two opening portions (first opening portion and second opening portion). The first opening portion overlaps with the emission region 120, and the second opening portion overlaps with the light-transmitting region 160. That is, the emission region 120 and the light-transmitting region 160 are defined by the first opening portion and the second opening portion. Note that, in each drawing for explaining the present embodiment and other embodiments described below, the light-shielding film 140 may not be provided in all of the regions indicated as the light-shielding film 140, and the light-shielding film may be arranged in a part of the region indicated as the light-shielding film 140. For example, the light-shielding film 140 may not be formed in all of or a part of the region overlapping with wirings described below.

Wirings for driving the light-emitting element disposed in each light-emitting region are arranged under the light-shielding film 140. For example, a gate line extending in a first direction (x direction in the drawing), a signal line and a current-supplying line extending in a second direction (y direction) perpendicular to the first direction, and the like are formed. At least two transistors are provided in each sub-pixel 100, and the transistors are driven with the aforementioned wirings by which the light-emitting element emits light at a predetermined luminance.

A part of the signal line and a part of the current-supplying line, which sandwich the light-transmitting region 160, are bent and may overlap with the emission region 120 of the adjacent sub-pixel 100 in the second direction. For example, the current-supplying line which is placed between the light-transmitting regions 160R and 160G to control the emission region 120R overlaps with the emission region 120G of the adjacent sub-pixel 100G in the second direction. In a similar way, the signal line which is placed between the emission regions 160R and 160G to control the emission region 120G overlaps with the emission region 120R of the adjacent sub-pixel 100R in the second direction. In other words, a part of the signal line and a part of the current-supplying line, which are adjacent to the light-transmitting region 160, are bent in the aforementioned structure.

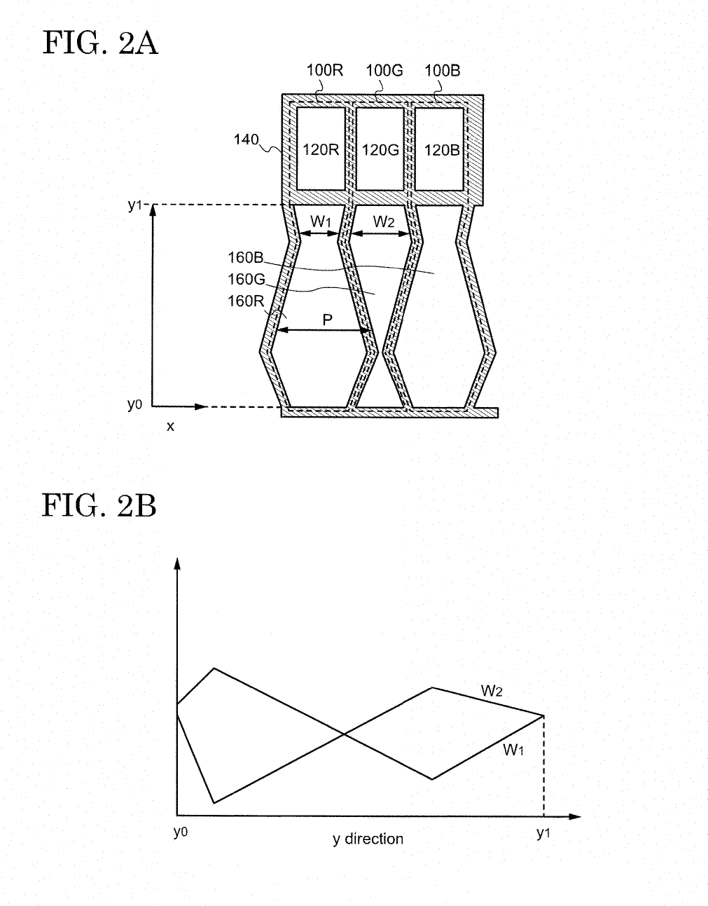

A part of the 12 sub-pixels 100 shown in FIG. 1 is shown in FIG. 2A. Here, a lateral direction and a longitudinal direction of the light-emitting region 160 are defined as a x direction (first direction) and a y direction (second direction), respectively, a length of the light-transmitting region 160R of the sub-pixel 100R in the x direction (that is, a width of the light-transmitting region) is defined as W₁, and a length of the light-transmitting region 160G of the sub-pixel 100G adjacent to the sub-pixel 100R is defined as W₂. As shown in FIG. 2B, as a position changes in the y direction from y0 to y1, W₁ linearly increases, linearly decreases, and then linearly increases again. On the other hand, as a position changes in the y direction from y0 to y1, W₂ linearly decreases, linearly increases, and then linearly decreases again. Namely, the width of the light-transmitting region 160 of the sub-pixel 100 of the present embodiment continuously changes along the y direction, and this change is expressed with a plurality of straight lines with one or more bending points sandwiched therebetween. Moreover, the change of the width continues in the whole of the second direction of the light-transmitting region 160.

Therefore, the light-transmitting regions (160R and 160G) of two adjacent sub-pixels (e.g., sub-pixels 100R and 100G) are different in shape and area therebetween. Moreover, a pitch P of the light-transmitting region 160 in the x direction continuously changes along the y direction in the whole of the y direction of the light-transmitting region 160. Furthermore, as shown in FIG. 1, the shape of the light-transmitting region 160 is different between the closest sub-pixels giving the same emission color.

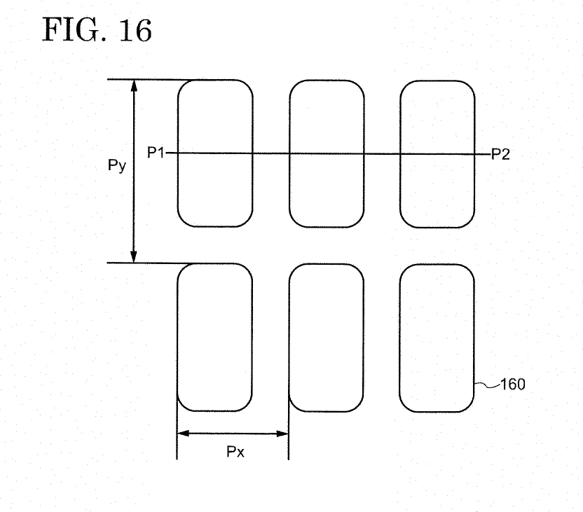

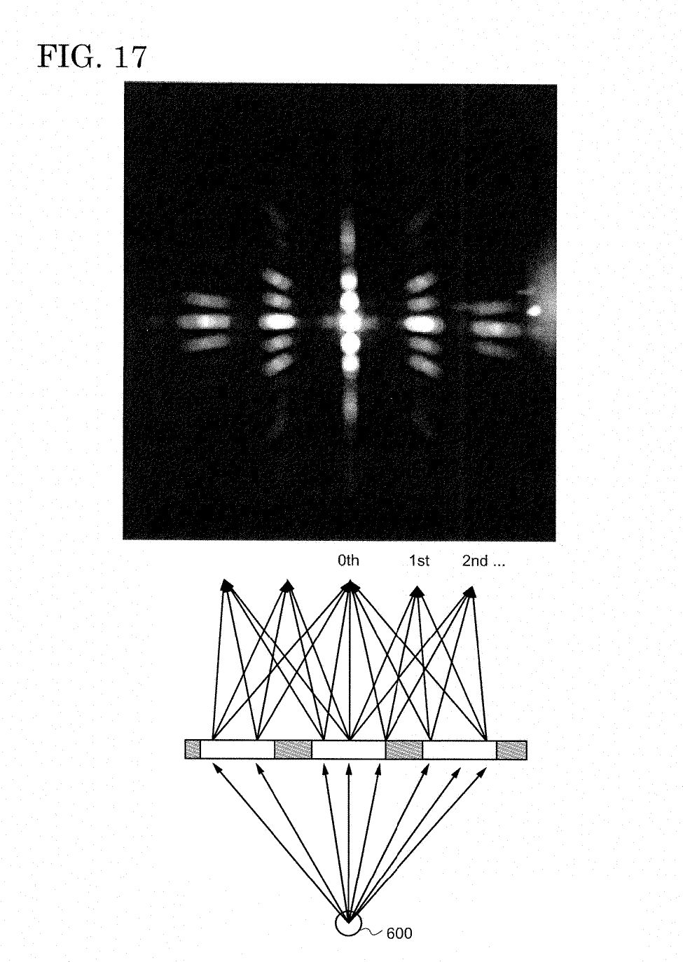

For example, as shown in FIG. 16, in a traditional transparent display device, the light-transmitting region 160 is generally the same in shape between the sub-pixels, and the width and length thereof are constant in the sub-pixel. Therefore, the pitches (Px and Py) of the light-transmitting region 160 are constant between the sub-pixels. As shown in FIG. 17, in the transparent display device having such a sub-pixel layout, light emitted from a light source 600 is diffracted when passing through the light-transmitting region 160 with a constant pitch shown in a cross-section P1-P2. As a result, a color change of the transmitting light occurs, and a viewing-angle dependence appears. Hence, quality of an image observed by transmitting ambient light is decreased. Additionally, the diffraction of the transmitting light causes reduction in quality of an image displayed by the transparent display device.

On the other hand, in the transparent display device shown in the present embodiment, the pitch P between the sub-pixels continuously changes along the y direction in the whole of the second direction of the light-transmitting region 160. Hence, the diffraction of the transmitting light can be suppressed without decreasing transmittance of the display device as a whole, and reduction in quality of an image observed by transmitting ambient light and an image displayed by the transparent display device can be prevented.

### 2. Structure of Sub-Pixel

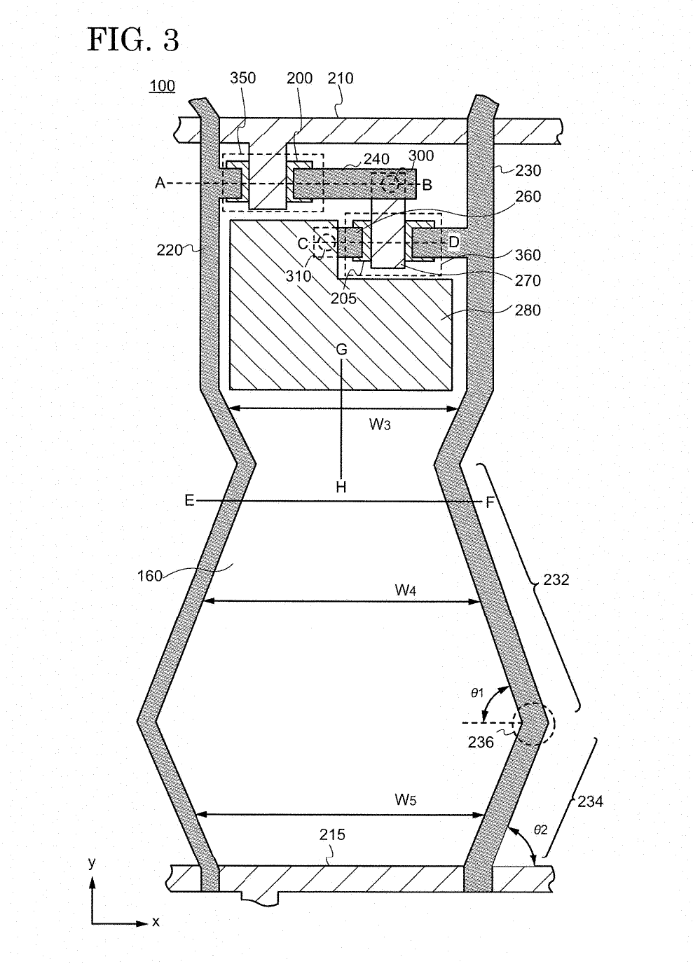

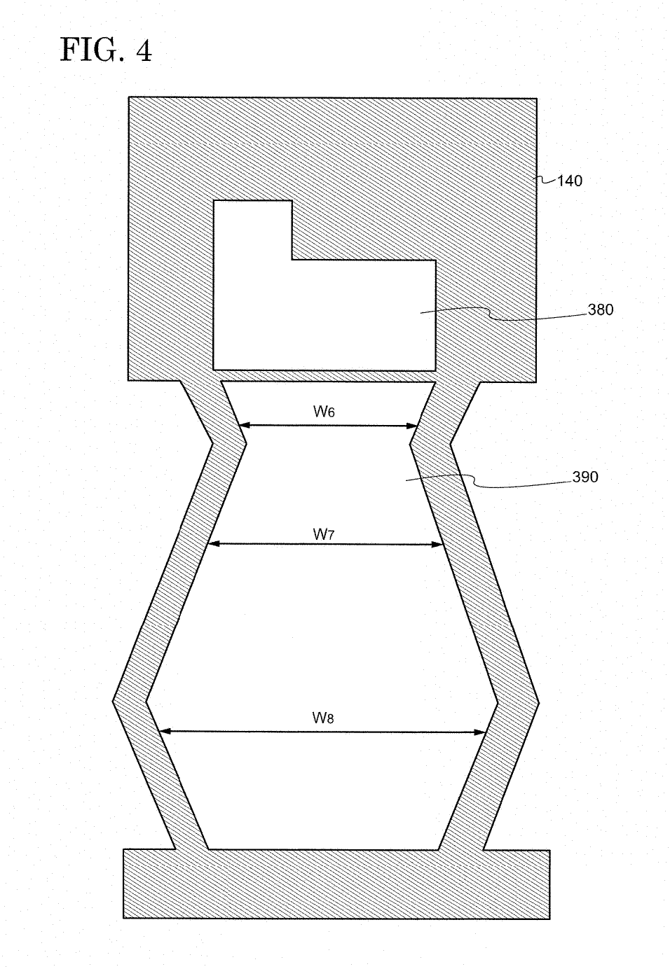

An example of a detailed structure of the sub-pixel 100 is explained by using FIG. 3. Note that the light-shielding film 140 provided over the sub-pixel 100 is omitted in FIG. 3, and a top view of the light-shielding film 140 is shown in FIG. 4.

The sub-pixel 100 possesses the gate lines 210 and 215 extending in the first direction (x direction in the drawing) and the signal line 220 and the current-supplying line 230 which extend in the second direction (y direction in the drawing) perpendicular to the first direction. A region surrounded by these gate lines 210 and 215, the signal line 220, and the current-supplying line 230 is the sub-pixel 100.

The sub-pixel 100 further has the transistors 350 and 360. The gate line 210 serves as a gate electrode of the transistor 350. The gate line 215 functions as a gate electrode of the transistor provided in the adjacent sub-pixel. The signal line 220 also works as a source electrode of the transistor 350, the transistor 350 is activated by the gate line 210, and a data signal input from the signal line 220 is transmitted to a wiring 240 functioning as a drain electrode of the transistor 350.

The data signal is further transmitted to a wiring 270 connected to the wiring 240 in a contact hole 300. The wiring 270 serves as a gate electrode of the transistor 360 and controls the on/off of a power source supplied from the current-supplying line 230. The power source supplied from the current-supplying line 230 is supplied to a wiring 260 which functions as a drain electrode of the transistor 360 through the transistor 360. The wiring 260 is connected to a first electrode 280 in a contact hole 310, and the power source is supplied to the first electrode 280.

A region in which the first electrode 280 directly contacts with an organic layer 465 (described below) formed thereover is the emission region 120. The first electrode 280 may be configured to transmit or reflect visible light. In the present embodiment, explanation is given for the case where the first electrode 280 is a reflective electrode reflecting visible light. In the present specification and claims, the light-transmitting region 160 means a region in which the light-emitting element is not provided and in which ambient light is able to pass therethrough. Furthermore, the light-transmitting region 160 can be formed between the emission region 120 and the gate line 215 which controls the adjacent sub-pixel.

As shown in FIG. 3, in the light-transmitting region 160, a distance in the first direction between the signal line 220 and the current-supplying line 230 continuously changes along the second direction in the whole of the second direction in the light-transmitting region 160. For example, in FIG. 3, the distances W₃, W₄, and W₃ are different from one another.

A portion of the signal line 220 and a portion of the current-supplying line 230, which sandwich the light-transmitting region 160, each have one or more bending points. Furthermore, the signal line 220 and the current-supplying line 230 each have at least two linear portions so as to sandwich the bending points. Angles between these linear portions and the first direction may be the same as or different from one another. For example, the current-supplying line 230 has a first linear portion 232 and a second linear portion 234 with a bending point 236 interposed therebetween. An angle θ1 between the first linear portion 232 and the first direction may be the same as or different from an angle 92 between the second linear portion 234 and the first direction.

The light-shielding film 140 is formed so as to overlap with the transistors 350 and 260, the gate lines 210 and 215, the signal line 220, the current-supplying line 230, and an edge portion of the first electrode 280 (FIG. 4). In other words, the light-shielding film 140 has the two opening portions (first opening portion 380 and second opening portion 390), and the emission region 120 and the light-transmitting region 160 are defined by the first opening portion 380 and the second opening portion 390, respectively.

The first opening portion 380 overlaps with the first electrode 280, and light obtained from the light-emitting element described below is extracted therethrough. On the other hand, the second opening portion 390 overlaps with the light-transmitting region 160. Note that, when widths of the signal line 220 and the current-supplying line 230 are smaller than a width of the corresponding portion of the light-shielding film 140, the light-transmitting region 160 is defined by the second opening portion 390 of the light-shielding film 140. Hence, the length W of the second opening portion 390 in the first direction also continuously changes along the y direction in the whole of the y direction of the second opening portion 390. For example, lengths W₆, W₇, and W₈ shown in FIG. 4 are different from one another. Moreover, this change is expressed with a plurality of straight lines, and a bending point exists between the straight lines.

### 3. Cross-Sectional Structure of Sub-Pixel

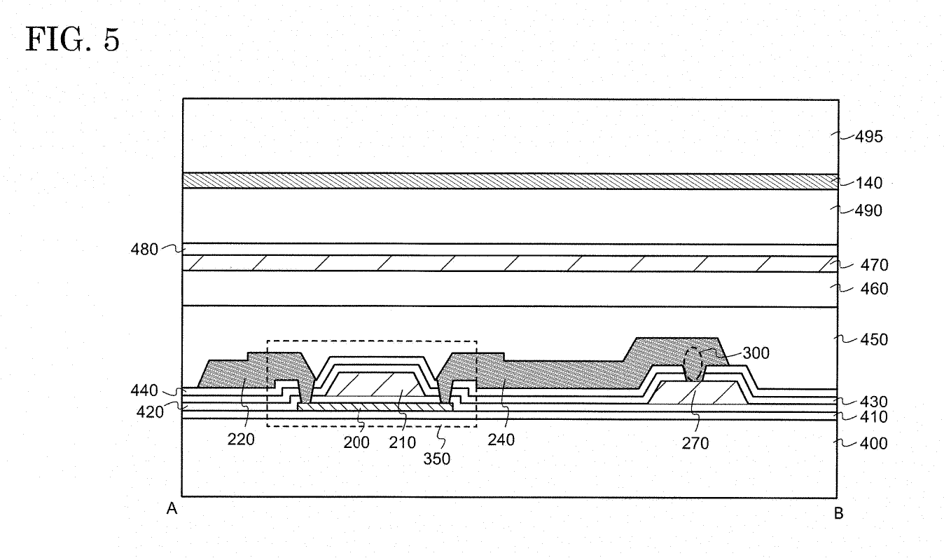

Cross-sectional views along straight lines A-B, C-D, E-F, and G-H of FIG. 3 are shown in FIG. 5 to FIG. 8, respectively. As shown in FIG. 5, the display device possesses a first substrate 400 and a base film 410 thereover. The base film 410 prevents diffusion of impurities from the first substrate 400 and is formed so as to include an insulating material such as silicon oxide, silicon oxynitride, and silicon oxide nitride. The base film 410 may have a single-layer structure or a stacked-layer structure.

The display device has a semiconductor film 200 over the base film 410. The semiconductor film 200 is formed by using a Group 14 element such as silicon and germanium or an oxide semiconductor. The semiconductor film 200 of a variety of crystal states such as amorphous, polycrystalline, single crystalline, and microcrystalline states can be used.

A gate insulating film 420 is provided over the semiconductor film 200. The gate insulating film 420 includes an inorganic insulating material such as silicon oxide, silicon oxynitride, and silicon oxide nitride and is formed in a single-layer structure or a stacked-layer structure. The gate line 210 and the wiring 270 are disposed over the gate insulating film 420, and a portion of the gate line 210, which overlaps with the semiconductor film 200, functions as the gate electrode of the transistor 350. The gate line 210 and the wiring 270 are prepared with a metal such as titanium, tungsten, molybdenum, aluminum, copper, and chromium or an alloy thereof in a single-layer structure or a stacked-layer structure. For example, a structure is represented in which a metal having high conductivity, such as copper and aluminum, is sandwiched by a metal such as molybdenum and titanium.

Protection films 430 and 440 are further provided over the gate line 210 and the wiring 270 of the display device. Similar to the gate insulating film 420, the protection films 430 and 440 are formed with an inorganic insulating material. Note that a structure having two layers of the protection films 430 and 440 is illustrated here. However, the protection film may have a single-layer structure.

The signal line 220 and the wiring 240 are formed over the gate insulating film 420 and the protection films 430 and 440. The signal line 220 and the wiring 240 are electrically connected to the semiconductor film 200 in contact holes formed in the gate insulating film 420 and the protection films 430 and 440, and a part of the signal line 220 and a part of the wiring 240 function as the source electrode and the drain electrode of the transistor 350, respectively. The wiring 240 is further electrically connected to the wiring 270 in the contact hole 300. A part of the wiring 270 functions as the gate electrode of the transistor 360 (see FIG. 3). The signal line 220 and the wiring 240 can be formed with a material which is the same as or similar to that of the gate line 210.

The display device further possesses an interlayer insulating film 450. The interlayer insulating film 450 is formed with an organic compound such as an acrylic resin and a polyimide resin in order to absorb steps caused by the transistor 350 and give a flat surface. Over the interlayer insulating film 450, an insulating film 460 functioning as an insulating film (bank) 460 (described below) which covers the edge of the first electrode 280, a second electrode 470 of the light-emitting element, and a protection film 480 over the second electrode 470 are disposed.

The display device further possesses the light-shielding film 140 to protect the transistors from ambient light. The light-shielding film 140 is formed with a metal material having low reflectance, such as chromium and titanium, a resin including a coloring material of black or a similar color, and the like. An overcoat film (not shown) may be provided so as to cover the light-shielding film 140. Note that the light-shielding film 140 is provided to a second substrate 495, and the first substrate 400 and the second substrate 495 are fixed so that the light-shielding film 140, the transistor 350, and the like are sealed between the first substrate 400 and the second substrate 495. In this case, a space 490 may be filled with an inert gas such as nitrogen and argon or a filler. A desiccant may be mixed in the filler.

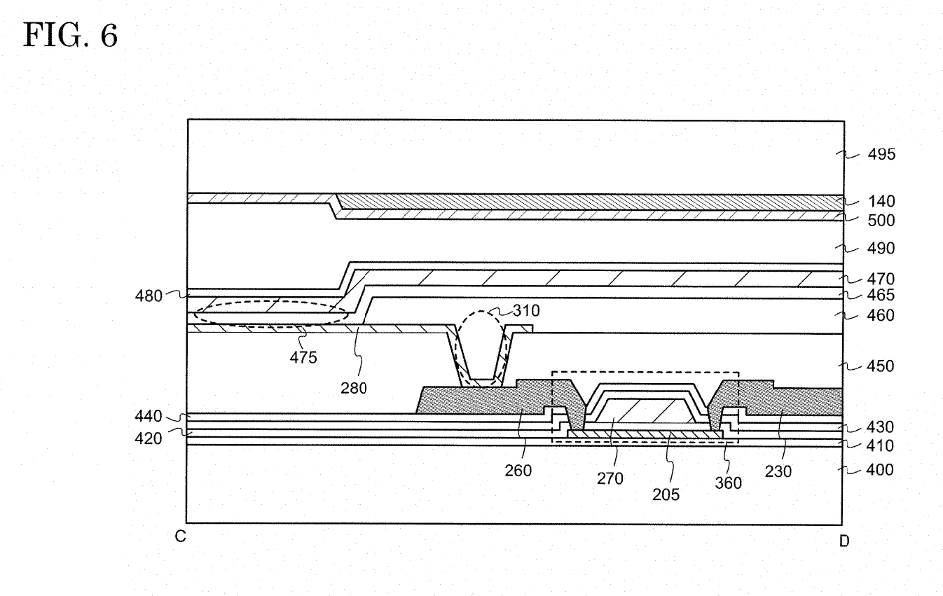

As shown in the cross section of FIG. 6, the display device has the transistor 360 over the base film 410, and the transistor 360 possesses a semiconductor film 205, the gate insulating film 420, the wiring 270, and the protection films 430 and 440. A portion of the wiring 270, which overlaps with the semiconductor film 205, functions as the gate electrode of the transistor 360. The current-supplying line 230 is formed over the protection film 440 and is electrically connected to the semiconductor film 205 through a contact hole formed in the gate insulating film 420 and the protection films 430 and 440. Therefore, a part of the current-supplying line 230 functions as the source electrode of the transistor 360. The wiring 260 is also formed over the protection film 440 and is electrically connected to the semiconductor film 205 through a contact hole formed in the gate insulating film 420, the protection film 430, and the protection film 440. The current-supplying line 230 and the wiring 260 can be formed with a material which is the same as or similar to that of the gate line 210.

A contact hole 320 reaching the wiring 260 is provided in the interlayer insulating film 450 in which the first electrode 280 is electrically connected thereto. The insulating film 460 is disposed so as to cover the edge portion of the first electrode 280 and the contact hole 320. The insulating film 460 also functions as a partition wall for electrically separating the adjacent sub-pixels 100 from each other. The insulating film 460 is formed by using an organic material such as an acrylic resin and a polyimide resin.

The organic layer 465 which undergoes light emission is arranged over the first electrode 280 over which the second electrode 470 is disposed. The light-emitting element 475 is structured by the first electrode 280, the organic layer 465, and the second electrode 470. When light-emission from the light-emitting element 475 is extracted from a side of the first electrode 400, the first electrode 280 is formed with a conductive oxide transmitting visible light, such as indium-tin oxide (ITO) and indium-zinc oxide (IZO). When the light-emission from the light-emitting element 475 is extracted from a second electrode 495 side, the first electrode 280 may be formed with a metal such as silver and aluminum or an alloy thereof. Alternatively, a structure in which a transparent conductive oxide such as ITO is stacked over these metals or a structure in which these metals are sandwiched by a transparent conductive oxide may be employed.

When the light emission obtained in the light-emitting element 475 is extracted from the side of the first substrate 400, a metal such as aluminum and magnesium or an alloy thereof can be used for the second electrode 470. On the other hand, when the light emission obtained in the light-emitting element 475 is extracted from the side of the second substrate 495, a transparent conductive oxide and the like are used. In this case, it is possible to decrease a driving voltage by forming magnesium or an alloy of magnesium and silver under a transparent conductive oxide at a thickness (approximately 1 nm to 10 nm) so as to transmit visible light. Furthermore, the second electrode 470 may be formed as a stacked structure in which a transparent conductive oxide is formed over a metal with a low work function. On the contrary, when a structure is employed in which the light-emission is extracted from both sides of the first substrate 400 and the second substrate 495, both the first electrode 280 and second electrode 470 may be configured to be transparent with respect to visible light. The present embodiment describes a structure where the first electrode 280 and the second electrode 470 reflect and transmit visible light, respectively.

At least a part of the organic layer 465 is formed with an organic material. The organic layer 465 is not limited to having a single-layer structure and may have a multi-layer structure including a variety of layers such as a hole-injection layer, a hole-transporting layer, an emission layer, an electron-transporting layer, an electron-injection layer, and a carrier-blocking layer. The organic layer 465 may be configured so as to give white emission or may be formed so that emission layers of three colors of red, blue, and green are formed in the respective sub-pixels, for example.

The protection film 480 is arranged over the second electrode 470. The protection film 480 may be formed so as to include an inorganic insulating material such as silicon nitride and silicon oxynitride.

The light-shielding film 140 is provided to the second substrate 495 so as to cover the transistor 360 and an edge portion of the light-emitting element 475. Additionally, a color filter 500 may be formed over the light-shielding film 140 (in FIG. 6, under the light-shielding film 140). When the organic layer 465 provides white emission, the light-emitting elements 475 of all of the sub-pixels 100 are formed with an organic layer 465 having a common structure, and the color filters 500 different in absorption property between the sub-pixels are disposed, by which a display device capable of full-color display is supplied. On the other hand, when the sub-pixels 100 are formed with three kinds of light-emitting elements 475 respectively giving one of the primary colors of red, green, and blue, the color filter 500 may not be formed.

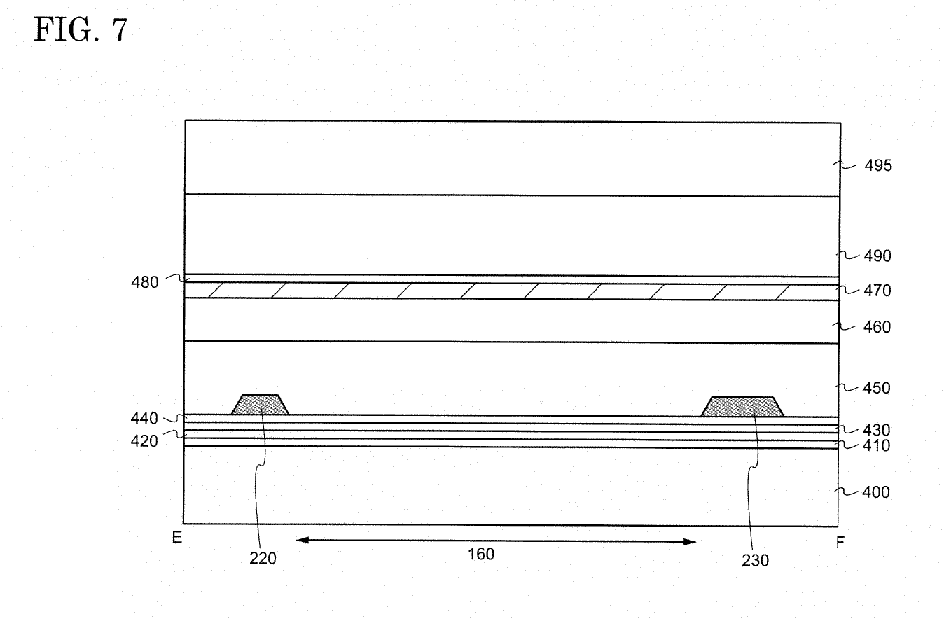

As shown in FIG. 7, in the light-transmitting region 160, any structure which partly or wholly absorbs or reflects visible light is not provided between the signal line 220 and the current-supplying line 230. Specifically, the display device has the base film 410, the gate insulating film 420, the protection films 430 and 440, the interlayer insulating film 450, the insulating film 460, the second electrode 470 having a light-transmitting property, the protection film 480, the space 490, and the second substrate 495 over the first substrate 400, and the light-shielding film 140 or the color filter 500 is not arranged in the light-transmitting region 160. This structure allows the light-transmitting region 160 to transmit visible light.

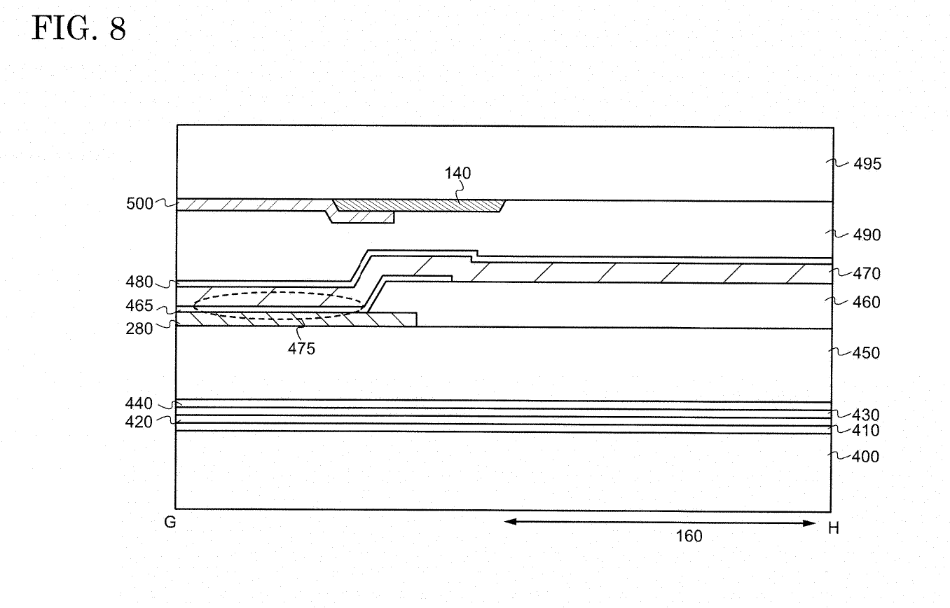

Referring to FIG. 8, the display device has the first electrode 280, the insulating film 460 covering the edge portion of the first electrode 280, the organic layer 465, the second electrode 470, the protection film 480, the space 490, the color filter 500, the light-shielding film 140, and the second substrate 495 over the interlayer insulating film 450. The light-shielding film 140 is formed so as to overlap with the edge portion of the light-emitting element 475. Moreover, any structure which partly or wholly absorbs or reflects visible light, such as the light-shielding film 140 and the color filter 500, is not provided in the light-transmitting region 160.

As described above, the display device shown in the present embodiment functions as a transparent display device in which each sub-pixel 100 has the light-transmitting region 160. The length (width) of the light-transmitting region 160 in the first direction continuously changes along the second direction in the whole of the light-transmitting region 160. Similarly, in each sub-pixel 100, the distance in the first direction between the signal line 220 and the current-supplying line 230 changes along the second direction in the whole of the second direction of the light-transmitting region 160. These changes are expressed with a plurality of straight lines with one or more bending points therebetween. Therefore, the pitch between sub-pixels continuously changes along the second direction. This structure enables it to suppress diffraction of the transmitting light without reduction of the transmittance of the display device as a whole, and reduction in quality of an image observed by transmitting ambient light and an image displayed by the transparent display device can be prevented.

### Second Embodiment

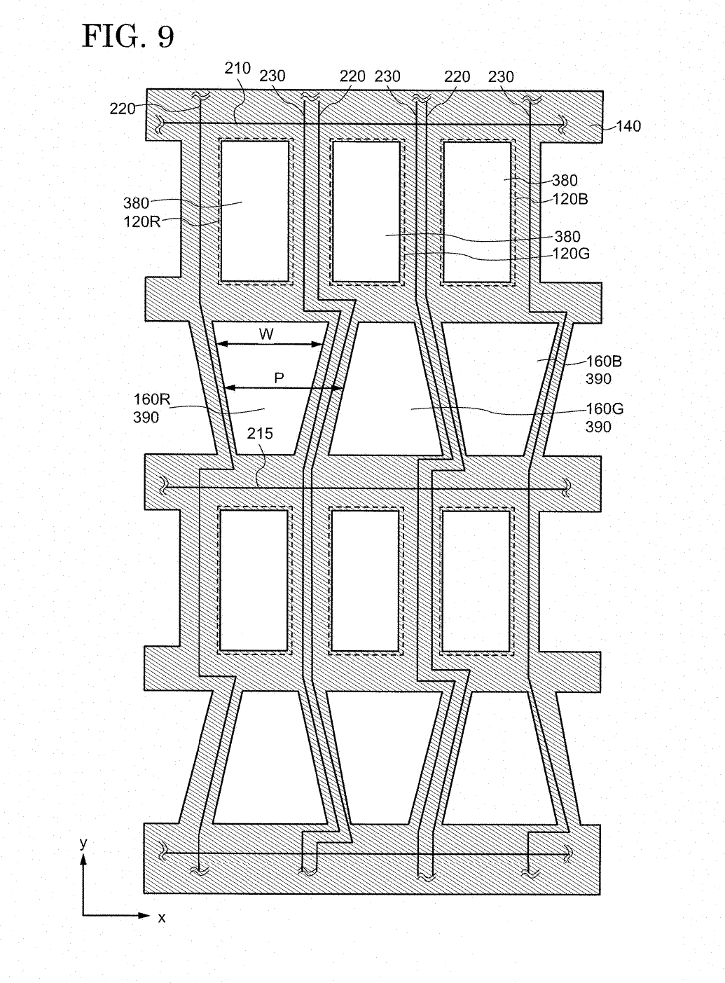

In the present embodiment, a structure of a transparent display device different from that of the First Embodiment is explained by using FIG. 9. Descriptions of structures which are the same as those of the First Embodiment are omitted.

In FIG. 9, the sub-pixels 100 arranged in a matrix form with two lines and three columns, the gate lines 210 and 215, the signal line 220, the current-supplying line 230, and the light-shielding film 140 are schematically illustrated. In each sub-pixel, the emission region 120, the light-transmitting region 160, the first opening portion 380 and the second opening 392 of the light-shielding film 140 are arranged. Since the light-transmitting region 160 is defined by the second opening portion 390, the light-transmitting region 160 and the second opening portion 390 overlap with each other.

As shown here, the length W of the light-transmitting region 160 in the direction in which the gate line 210 extends changes continuously and linearly in the second direction perpendicular to the first direction in the whole of the second direction of the light-transmitting region 160. Furthermore, the direction of the change is different between the adjacent sub-pixels. Specifically, the length W in the first direction increases along the second direction (y direction in the drawing) in the light-transmitting region 160R but decreases along the second direction in the adjacent light-transmitting region 160G. In the further adjacent light-transmitting region 160G, the length W increases along the second direction. Therefore, the pitch P between the sub-pixels 100 also continuously changes along the second direction. Note that, apart from the First Embodiment, the change of the length W of the light-transmitting region 160 in the first direction along the second direction is expressed with a single straight line, and no bending point is included in the light-transmitting region 160.

Therefore, in a portion of the signal line 220 and a portion of the current-supplying line 230, which sandwich the light-transmitting region 160, the direction between these wirings in the first direction continuously changes in the second direction perpendicular to the first region in the whole of the second direction of the light-transmitting region 160. Additionally, the direction of this change is different between the sub-pixels. In the present embodiment, a portion of the signal line 220 and a portion of the current-supplying line 230, which sandwich the light-transmitting region 160, are expressed by a single straight line without any bending point.

With this structure, the diffraction of the transmitting light can be suppressed without decreasing transmittance of the display device as a whole, and reduction in quality of an image observed by transmitting ambient light and an image displayed by the transparent display device can be prevented. Moreover, since the number of the bending points of the signal line 220 and the current-supplying line 230 is small, the layout of the sub-pixels can be readily designed.

### Third Embodiment

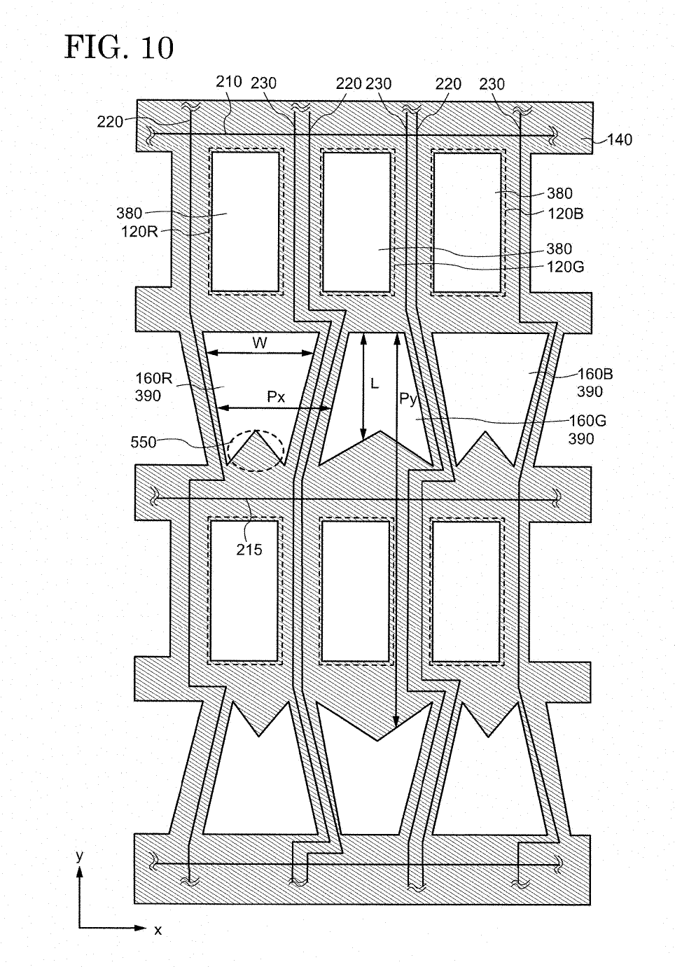

In the present embodiment, a structure of a transparent display device which is different from those of the aforementioned Embodiments is explained by using FIG. 10. Description regarding the structures which are the same as those of the aforementioned Embodiments is omitted.

In FIG. 10, the sub-pixels arranged in a matrix form with two lines and three columns, the gate lines 210 and 215, the signal line 220, the current-supplying line 230, and the light-shielding film 140 are schematically shown. In each sub-pixel, the emission region 120, the light-transparent region 160, the first opening portion 380 and the second opening portion 390 of the light-shielding film 140 are provided. Since the light-transmitting region 160 is defined by the second opening portion 390, the light-transmitting region 160 overlaps with the second opening portion 390 in the drawing.

As shown here, the length W of the light-transmitting region 160 in the first direction in which the gate lines 210 and 215 extend changes continuously in the second direction perpendicular to the first direction in the whole of the second direction of the light-transmitting region 160. Moreover, the direction of the change is different between the adjacent sub-pixels. Specifically, the length W of the first direction increases along the second direction (y direction in the drawing) in the light-transmitting region 160R but decreases along the second direction in the adjacent light-transmitting region 160G. In the further adjacent light-transmitting region 160G, the length W increases along the second direction. Therefore, the pitch Px between the sub-pixels 100 also continuously changes along the second direction.

Therefore, in a portion of the signal line 220 and a portion of the current-supplying line 230, which sandwich the light-transmitting region 160, the distance in the first direction between these wirings continuously and linearly changes along the second direction perpendicular to the first direction in the whole of the second direction of the light-transmitting region 160. Moreover, the direction of the change is different between the adjacent sub-pixels. In the present embodiment, a portion of the signal line 220 and a portion of the current-supplying line, which sandwich the light-transmitting region 160, are expressed by a single straight line and do not have a bending point.

In the display device of the present embodiment, the light-shielding film 140 further has a projected portion 550 having a triangle shape in each light-transmitting region 160. Therefore, a length L of the light-transmitting region 160 in the second direction continuously changes along the first direction in the whole of the first direction of the light-transmitting region 160. Additionally, the change is expressed by a plurality of straight lines with a bending point therebetween, and a magnitude of the change is different between the adjacent sub-pixels. Specifically, the change of the length L in the second direction in the light-transmitting region 160R is larger than that in the adjacent light-transmitting region 160G. Hence, the pitch Py between the sub-pixels 100 in the second direction also continuously changes along the first direction.

In the present embodiment, the projected portion 550 has a triangle shape. However, the projected portion 550 is not limited to this shape and may be polygonal or have a curved shape. This projected portion 550 is described as a part of the light-transmitting film 140. However, the projected portion 550 is not limited to this structure and may be prepared by utilizing a part of the gate line.

With this structure, the diffraction of the transmitting light can be suppressed without decreasing transmittance of the display device as a whole, and reduction in quality of an image observed by transmitting ambient light and an image displayed by the transparent display device can be prevented.

### Fourth Embodiment

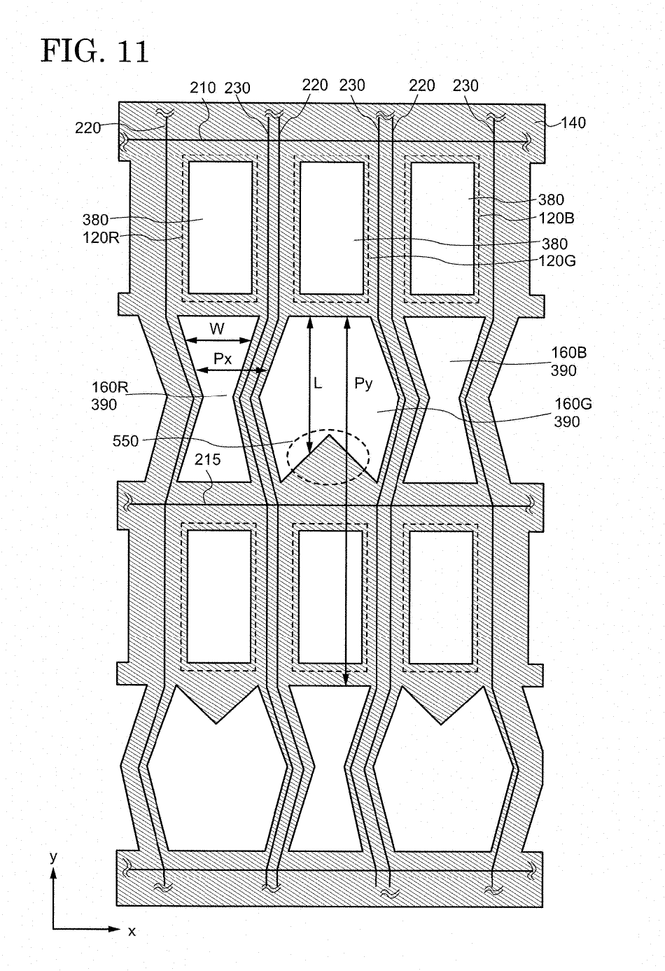

In the present embodiment, a structure of a transparent display device which is different from those of the aforementioned Embodiments is explained by using FIG. 11. Description regarding the structures which are the same as those of the aforementioned Embodiments is omitted.

In FIG. 11, the sub-pixels arranged in a matrix form with two lines and three columns, the gate lines 210 and 215, the signal line 220, the current-supplying line 230, and the light-shielding film 140 are schematically shown. In each sub-pixel, the emission region 120, the light-transparent region 160, the first opening portion 380 and the second opening portion 390 of the light-shielding film 140 are provided. Since the light-transmitting region 160 is defined by the second opening portion 390, the light-transmitting region 160 overlaps with the second opening portion 390 in the drawing.

As shown here, the length W of the light-transmitting region 160 in the first direction in which the gate lines 210 and 215 extend changes continuously in the second direction perpendicular to the first direction in the whole of the first direction of the light-transmitting region 160. Moreover, the change is expressed by the two straight lines with one bending point interposed therebetween. Hence, the layout of each wiring is facilitated. Additionally, the direction of the change is different between the adjacent sub-pixels. Specifically, the length W in the first direction decreases and then increases along the second direction (y direction in the drawing) in the light-transmitting regions 160R and 160B but increases and then decreases along the second direction in the adjacent light-transmitting region 160G. Therefore, the pitch Px between the sub-pixels 100 also continuously changes along the second direction.

Therefore, in a portion of the signal line 220 and a portion of the current-supplying line 230, which sandwich the light-transmitting region 160, the distance in the first direction between these wirings continuously and linearly changes along the second direction perpendicular to the first direction in the whole of the second direction of the light-transmitting region 160. Moreover, the direction of the change is different between the adjacent sub-pixels. In the present embodiment, a portion of the signal line 220 and a portion of the current-supplying line, which sandwich the light-transmitting region 160, are expressed by two straight lines with a bending point interposed therebetween.

In the display device of the present embodiment, the light-shielding film 140 further has a projected portion 550 having a triangle shape in the second opening portion 390, and this projected portion 550 is selectively arranged in only one of the continuously arranged three sub-pixels. In the light-transmitting region 160G in which the projected portion is formed, the length L in the second direction continuously changes along the first direction in the whole of the first direction of the light-transmitting region 160, and the change of the length L is different between adjacent sub-pixels. Specifically, in the light-transmitting region 160G, the length L in the second direction continuously changes, and this change is expressed by two straight lines with a bending point interposed therebetween. However, in the adjacent light-transmitting regions 160R and 1608, the length L is constant in a partial area. Hence, the pitch Py between the sub-pixels 100 in the second direction also continuously changes along the first direction.

In the present embodiment, the projected portion 550 has a triangle shape. However, the projected portion 550 is not limited to this shape and may be polygonal or have a curved shape. This projected portion 550 is described as a part of the light-transmitting film 140. However, the projected portion 550 is not limited to this structure and may be prepared by utilizing a part of the gate line.

With this structure, the diffraction of the transmitting light can be suppressed without decreasing transmittance of the display device as a whole, and reduction in quality of an image observed by transmitting ambient light and an image displayed by the transparent display device can be prevented.

### Fifth Embodiment

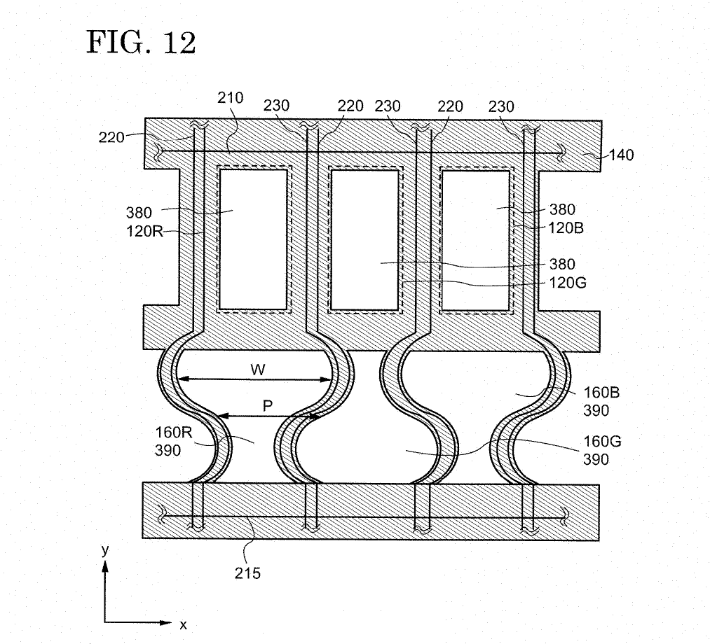

In the present embodiment, a structure of a transparent display device which is different from those of the aforementioned Embodiments is explained by using FIG. 12. Description regarding the structures which are the same as those of the aforementioned Embodiments is omitted.

In FIG. 12, the sub-pixels arranged in a matrix form with one line and three columns, the gate lines 210 and 215, the signal line 220, the current-supplying line 230, and the light-shielding film 140 are schematically shown. In each sub-pixel, the emission region 120, the light-transparent region 160, the first opening portion 380 and the second opening portion 390 of the light-shielding film 140 are provided. Since the light-transmitting region 160 is defined by the second opening portion 390, the light-transmitting region 160 overlaps with the second opening portion 390 in the drawing.

As shown here, the length W of the light-transmitting region 160 in the first direction in which the gate lines 210 and 215 extend changes curvedly along the second direction perpendicular to the first direction in the whole of the second direction of the light-transmitting region 160. Moreover, the change is expressed by a curve having an inflection point. Additionally, the direction of the change is different between the adjacent sub-pixels. Specifically, the length W of the first direction decreases, increases, and then decreases again along the second direction (y direction in the drawing) in the light-transmitting regions 160R and 160B but increases, decreases, and then increases again along the second direction in the adjacent light-transmitting region 160G. Therefore, the pitch P between the sub-pixels 100 also continuously changes along the second direction. Note that an example is shown in which the change of the length W is expressed by a curve with one inflection point. However, the light-transmitting region 160 may be configured so that the change of the length W is expressed by a curve having a plurality of inflection points.

Therefore, in a portion of the signal line 220 and a portion of the current-supplying line 230, which sandwich the light-transmitting region 160, the distance in the first direction between these wirings continuously and curvedly changes along the second direction perpendicular to the first direction in the whole of the second direction of the light-transmitting region 160. Moreover, the direction of the change is different between the adjacent sub-pixels. In the present embodiment, a portion of the signal line 220 and a portion of the current-supplying line, which sandwich the light-transmitting region 160, are expressed by a curve with an inflection point. However, these wirings are not limited to this mode and may be configured to be expressed with a curve with a plurality of inflection points.

With this structure, the diffraction of the transmitting light can be suppressed without decreasing transmittance of the display device as a whole, and reduction in quality of an image observed by transmitting ambient light and an image displayed by the transparent display device can be prevented.

### Sixth Embodiment

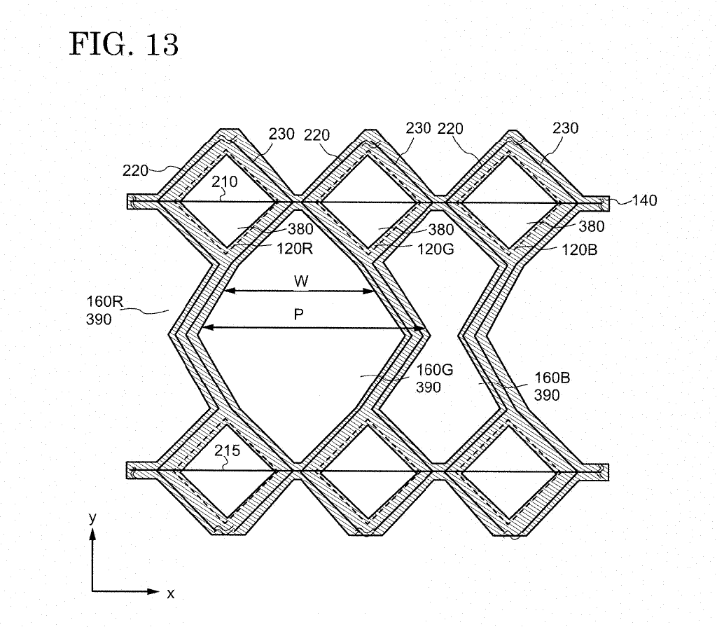

In the present embodiment, a structure of a transparent display device which is different from those of the aforementioned Embodiments is explained by using FIG. 13. Description regarding the structures which are the same as those of the aforementioned Embodiments is omitted.

In FIG. 13, the sub-pixels arranged in a matrix form with one line and three columns, the gate lines 210 and 215, the signal line 220, the current-supplying line 230, and the light-shielding film 140 are schematically shown. In each sub-pixel, the emission region 120, the light-transparent region 160, the first opening portion 380 and the second opening portion 390 of the light-shielding film 140 are provided. Since the light-transmitting region 160 is defined by the second opening portion 390, the light-transmitting region 160 overlaps with the second opening portion 390 in the drawing.

As shown here, in the present embodiment, each emission region 120 is arranged in a diamond-shaped layout. Hence, it is possible to secure the light-transmitting region 160 having a large area, and transmittance of the whole of the display device is increased.

In the light-transmitting region 160, the length W in the first direction in which the gate lines 210 and 215 extend changes linearly along the second direction perpendicular to the first direction in the whole of the second direction of the light-transmitting region 160. Moreover, the direction of the change is different between the adjacent sub-pixels. Specifically, the length W in the first direction increases and then decreases along the second direction (y direction in the drawing) in the light-transmitting regions 160G but increases, decreases, increases again, and then decreases in the adjacent light-transmitting region 160B. Therefore, the pitch P between the sub-pixels 100 also continuously changes along the second direction.

Therefore, in a portion of the signal line 220 and a portion of the current-supplying line 230, which sandwich the light-transmitting region 160, the distance in the first direction between these wirings continuously and linearly changes along the second direction perpendicular to the first direction in the whole of the second direction of the light-transmitting region 160. Moreover, the direction of the change is different between the adjacent sub-pixels. In the present embodiment, a portion of the signal line 220 and a portion of the current-supplying line, which sandwich the light-transmitting region 160, are expressed by two straight lines with a bending point sandwiched therebetween.

With this structure, the diffraction of the transmitting light can be suppressed without decreasing transmittance of the display device as a whole, and reduction in quality of an image observed by transmitting ambient light and an image displayed by the transparent display device can be prevented.

### Seventh Embodiment

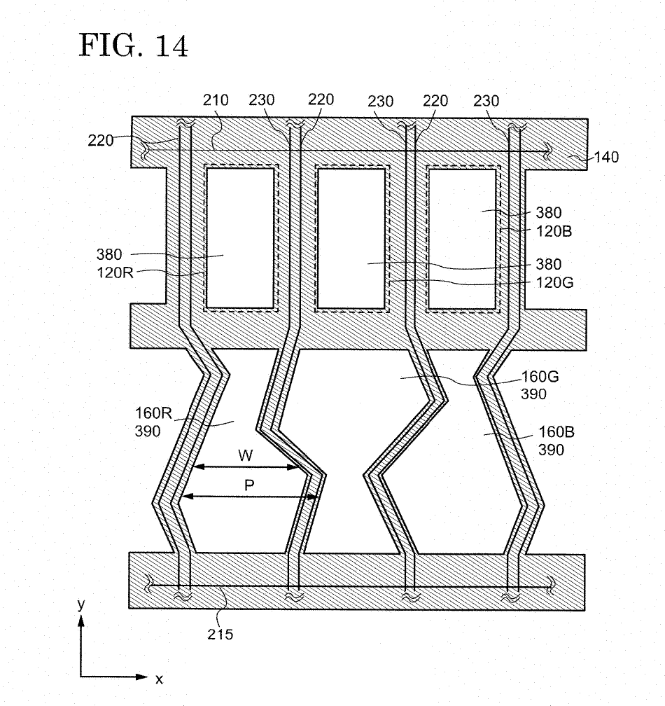

In the present embodiment, a structure of a transparent display device which is different from those of the aforementioned Embodiments is explained by using FIG. 14. Description regarding the structures which are the same as those of the aforementioned Embodiments is omitted.

In FIG. 14, the sub-pixels arranged in a matrix form with one line and three columns, the gate lines 210 and 215, the signal line 220, the current-supplying line 230, and the light-shielding film 140 are schematically shown. In each sub-pixel, the emission region 120, the light-transparent region 160, the first opening portion 380 and the second opening portion 390 of the light-shielding film 140 are provided. Since the light-transmitting region 160 is defined by the second opening portion 390, the light-transmitting region 160 overlaps with the second opening portion 390 in the drawing.

As shown here, in the light-transmitting region 160, the length W in the first direction in which the gate lines 210 and 215 extend changes linearly along the second direction perpendicular to the first direction in the whole of the second direction of the light-transmitting region 160. Moreover, this change is expressed by a plurality of straight lines with a plurality of bending points.

Therefore, in a portion of the signal line 220 and a portion of the current-supplying line 230, which sandwich the light-transmitting region 160, the distance in the first direction between these wirings continuously and linearly changes along the second direction perpendicular to the first direction in the whole of the second direction of the light-transmitting region 160. Moreover, the direction of the change is different between the adjacent sub-pixels. Additionally, these portions are expressed by a plurality of straight lines with a plurality of bending points. Furthermore, the coordinates of the bending points in the signal line 220 and the bending points of the current-supplying line 230 are different in the second direction. Thus, a change in the pitch P between the sub-pixels becomes more complicated.

With this structure, the diffraction of the transmitting light can be suppressed without decreasing transmittance of the display device as a whole, and reduction in quality of an image observed by transmitting ambient light and an image displayed by the transparent display device can be prevented. Furthermore, the aforementioned effect can be more strongly obtained due to the complicated change of the pitch P between the sub-pixels.

### Eighth Embodiment

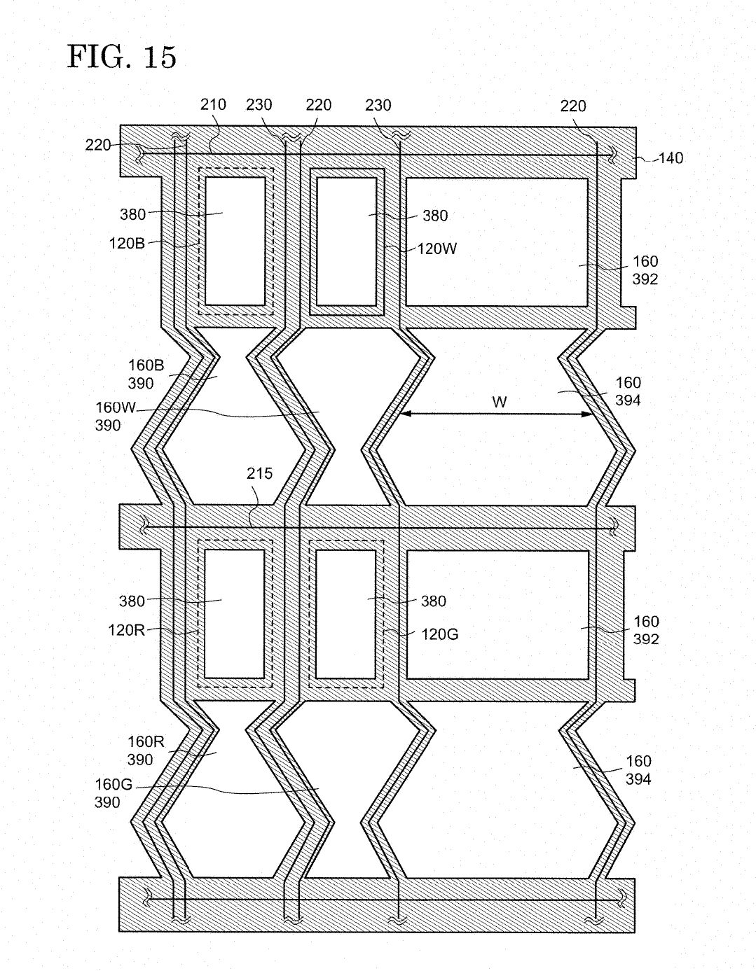

In the present embodiment, a structure of a transparent display device which is different from those of the aforementioned Embodiments is explained by using FIG. 15. Description regarding the structures which are the same as those of the aforementioned Embodiments is omitted.

In FIG. 15, the sub-pixels arranged in a matrix form with two lines and two columns, the gate lines 210 and 215, the signal line 220, the current-supplying line 230, and the light-shielding film 140 are schematically shown. In each sub-pixel, the emission region 120, the light-transparent region 160, the first opening portion 380 and the second opening portion 390 of the light-shielding film 140 are provided. Since the light-transmitting region 160 is defined by the second opening portion 390, the light-transmitting region 160 overlaps with the second opening portion 390 in the drawing.

In the present embodiment, sub-pixels giving red, green, and blue, and white emissions are arranged, and the emission regions thereof correspond to 120R, 120G, 1208, and 120W, respectively. The light-transmitting region 160 is not only provided in each sub-pixel, but also disposed in a region adjacent to two adjacent sub-pixels which are continuously arranged. Specifically, the light-shielding film 140 has not only the first opening portion 380 and the second opening portion 390, but also a third opening portion 392 and a fourth opening portion 394 in a region which does not overlap with the sub-pixels. In the third opening portion 392, a length in the first direction in which the gate lines 210 and 215 extend is constant, and a length of the second direction perpendicular to the first direction is also constant. On the other hand, a length W in the first direction of the fourth opening portion 394 continuously changes along the second direction in the whole of the second direction of the fourth opening portion 394. This change is expressed by a plurality of straight lines with bending points interposed therebetween.

Therefore, in a portion of the signal line 220 and a portion of the current-supplying line 230, which sandwich the light-transmitting region 160, the distance in the first direction between these wirings continuously and linearly changes along the second direction perpendicular to the first direction in the whole of the second direction of the light-transmitting region 160. Moreover, the direction of the change is different between the adjacent sub-pixels. In the present embodiment, a portion of the signal line 220 and a portion of the current-supplying line 230, which sandwich the light-transmitting region 160, are expressed by a plurality of straight lines with a plurality of bending points.

With this structure, the diffraction of the transmitting light can be suppressed without decreasing transmittance of the display device as a whole, and reduction in quality of an image observed by transmitting ambient light and an image displayed by the transparent display device can be prevented. The present embodiment allows the production of a transparent display device having higher transmittance because the area ratio of the light-transmitting region 160 is higher compared with that of other embodiments.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

In the present specification, the parameters such as the distance in the first direction between the signal line 200 and the current-supplying line 230 of each sub-pixel 100, the distance in the second direction between the signal line 200 and the current-supplying line 230 of each sub-pixel 100, the length of the second opening portion in the first direction, the length of the second opening portion in the second direction, the pitch of the sub-pixel in the first direction, and the pitch of the sub-pixel in the second direction continuously change at least along the first direction or the second direction. However, the continuous change means a substantially continuous change. Therefore, the parameters may not continuously change and may be constant in a part of the light-transmitting region 160.

In the specification, although the cases of the organic EL display device are exemplified, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by persons ordinarily skilled in the art.

1. A display device comprising:
a first substrate;
a first gate line and a second gate line located over the first substrate and extend in a first direction;
a signal line and a current-supplying line located over the first substrate and extend in a second direction intersecting with the first direction;
a first sub-pixel surrounded by the first gate line, the second gate line, the signal line, and the current-supplying line; and
a light-shielding film located over the first sub-pixel and having a first opening portion and a second opening portion,
wherein the first sub-pixel overlaps with the first opening portion and the second opening portion and comprises an emission region and a light-transmitting region, and
wherein, in the light-transmitting region, a distance in the first direction between the signal line and the current-supplying line continuously changes along the second direction.

2. The display device according to claim 1,
wherein the signal line overlaps with an emission region of a second sub-pixel adjacent to the first sub-pixel in the second direction.

3. The display device according to claim 1,
wherein a length of the light-transmitting region in the second direction continuously changes along the first direction.

4. The display device according to claim 1,
wherein an area of the light-transmitting region is different from an area of a light-transmitting region of a second sub-pixel adjacent to the first sub-pixel.

5. The display device according to claim 1,
wherein a shape of the light-transmitting region is different from a shape of a light-transmitting region of a second sub-pixel adjacent to the first sub-pixel.

6. The display device according to claim 1,
wherein a shape of the light-transmitting region is different from a shape of a light-transmitting region of a second sub-pixel closest to the first sub-pixel and gives the same emission color as the first sub-pixel.

7. The display device according to claim 1,
wherein a length of the second opening portion in the first direction continuously changes along the second direction.

8. The display device according to claim 1,
wherein a length of the second opening portion in the second direction continuously changes along the first direction.

9. A display device comprising:
a first substrate;
a first gate line and a second gate line located over the first substrate and extend in a first direction;
a signal line and a current-supplying line located over the first substrate and extend in a second direction intersecting with the first direction;
a first sub-pixel surrounded by the first gate line, the second gate line, the signal line, and the current-supplying line; and
a light-shielding film located over the first sub-pixel and having a first opening portion and a second opening portion,
wherein the first sub-pixel overlaps with the first opening portion and the second opening portion and comprises an emission region and a light-transmitting region, and
wherein a portion of the signal line and a portion of the current-supplying line which are adjacent to the light-transmitting region have a bending point.

10. The display device according to claim 9,
wherein the signal line comprises a first linear portion and a second linear portion with the bending point therebetween, and
wherein an angle between the first linear portion and the first direction is different from an angle between the second linear portion and the first direction.

11. The display device according to claim 9,
wherein the current-supplying line comprises a first linear portion and a second linear portion with the bending point therebetween, and
wherein an angle between the first linear portion and the first direction is different from an angle between the second linear portion and the first direction.

12. The display device according to claim 9,
wherein a portion of the signal line and a portion of the current-supplying line adjacent to the light-transmitting region each have a plurality of bending points.

13. A display device comprising:
a first emission region;
a second emission region adjacent to the first emission region in a first direction;
a first light-transmitting region adjacent to the first emission region in a second direction intersecting with the first direction; and
a second light-transmitting region adjacent to the first light-transmitting region in the first direction and adjacent to the second emission region in the second direction,
wherein a distance of the first light-transmitting region in the first direction includes a first distance and a second distance smaller than the first distance.

14. The display device according to claim 13,
wherein a distance of the second light-transmitting region in the first direction includes a third distance and a fourth distance smaller than the third distance.

15. The display device according to claim 13,
wherein the distance of the first light-transmitting region in the first direction continuously changes.

16. The display device according to claim 13, further comprising:
a wiring between the first light-transmitting region and the second light-transmitting region, the wiring comprising a bending point between the first light-transmitting region and the second light-transmitting region.

17. The display device according to claim 13, further comprising:
a wiring between the first light-transmitting region and the second light-transmitting region, the wiring being bent between the first light-transmitting region and the second light-transmitting region.

18. The display device according to claim 14,
wherein the distance of the first light-transmitting region in the first direction continuously changes.

19. The display device according to claim 14, further comprising:
a wiring between the first light-transmitting region and the second light-transmitting region, the wiring comprising a bending point between the first light-transmitting region and the second light-transmitting region.

20. The display device according to claim 14, further comprising:
a wiring between the first light-transmitting region and the second light-transmitting region, the wiring being bent between the first light-transmitting region and the second light-transmitting region.
